(19) United States
(12) Patent Application Publication
(10) Pub. No.: US 2026/0006924 A1
(43) Pub. Date: Jan. 1, 2026

(54) METHOD FOR MANUFACTURING IMAGE SENSING DEVICE AND IMAGE SENSING DEVICE

(71) Applicant: TONG HSING ELECTRONIC INDUSTRIES, LTD., Taoyuan City (TW)

(72) Inventors: JUI-HUNG HSU, Taoyuan City (TW); LI-CHUN HUNG, Taoyuan City (TW)

(21) Appl. No.: 18/909,033

(22) Filed: Oct. 8, 2024

(30) Foreign Application Priority Data
Jun. 28, 2024 (TW) 113124150

(51) Int. Cl. H01L 27/146

(52) U.S. Cl. CPC H10F 39/804; H10F 39/011; H10F 39/811

(57) ABSTRACT

A method for manufacturing an image sensing device and an image sensing device are provided. The method includes steps as follows. An image sensing chip is fixed on an upper surface of a carrier substrate. Metal wires are provided to respectively connect chip pads of an image sensing chip with substrate pads of the carrier substrate. A cover board is provided, and a limiting dam is formed on a bottom surface of the cover board. The limiting dam is arranged to surround a sensing area of the image sensing chip and is fixed between the sensing area and the substrate pads. Then, the cover board and the limiting dam are removed. A sealing material wall covers the chip pads and completely covers the metal wires. Finally, the cover board covers above the image sensing chip, and is adhered to the sealing material wall by an adhesive layer.

### CROSS-REFERENCE TO RELATED PATENT APPLICATION

This application claims the benefit of priority to Taiwan Patent Application No. 113124150, filed on Jun. 28, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a method for manufacturing an image sensing device and an image sensing device, and more particularly to an image sensing device that includes an image sensing chip and can be used to capture images to form digital signals, and a method for manufacturing the image sensing device.

### BACKGROUND OF THE DISCLOSURE

Image sensing devices are widely applied in various electronic devices to obtain images, and image sensing chips are crucial to the image sensing devices. The trend of development of the image sensing chips is that a sensing area of an image sensing chip becomes larger and larger. Under a same chip area, the width between the sensing area of the image sensing chip and the edge of the image sensing chip becomes smaller and smaller. However, an area outside of the sensing area of the image sensing chip needs glue dispensing so as to be adhered to a transparent cover board.

The above-mentioned trend of development has increasingly raised the difficulty of glue dispensing. Accordingly, the reliability of the packaging structure of the image sensing device is reduced.

Therefore, how to improve the packaging effect of the image sensing device has become one of the issues to be addressed in the relevant art.

### SUMMARY OF THE DISCLOSURE

In response to the above-referenced technical inadequacy, the present disclosure provides a method for manufacturing an image sensing device to overcome the above-mentioned problems.

In one aspect, the present disclosure provides a method for manufacturing an image sensing device. The method for manufacturing the image sensing device includes at least the following steps: fixing an image sensing chip on an upper surface of a carrier substrate; providing a plurality of metal wires to respectively connect a plurality of chip pads of the image sensing chip with a plurality of substrate pads of the carrier substrate; providing a cover board, and a limiting dam being formed on a bottom surface of the cover board, the limiting dam including a thermoplastic material adjacent to the cover board; arranging the limiting dam to surround the sensing area of the image sensing chip, and fixing the limiting dam between the sensing area and the plurality of substrate pads; removing the cover board to separate the cover board from the limiting dam; disposing a sealing material wall that extends outward from an outer side surface of the limiting dam to cover the plurality of chip pads and fully cover the plurality of metal wires; coating an adhesive layer on a top surface of the limiting dam and extending the adhesive layer to an outer bevel of the sealing material wall; and covering the cover board above the image sensing chip, and adhering the cover board to the top surface of the limiting dam and the sealing material wall through the adhesive layer.

In another aspect, the present disclosure provides an image sensing device. The image sensing device includes a carrier substrate, an image sensing chip, a plurality of metal wires, a limiting dam, a sealing material wall, an adhesive layer, and a cover board. An upper surface of the carrier substrate includes a plurality of substrate pads. A rear surface of the image sensing chip is fixed on the upper surface of the carrier substrate. A top surface of the image sensing chip has a sensing area and a plurality of chip pads. The plurality of metal wires are respectively connected between the plurality of substrate pads and the plurality of chip pads. The limiting dam is arranged on the top surface of the image sensing chip. The limiting dam is located between the sensing area and the plurality of substrate pads. The sealing material wall extends outward from an outer side surface of the limiting dam. The sealing material wall covers the plurality of chip pads and fully covers the plurality of metal wires. The adhesive layer is disposed on a top surface of the limiting dam and extends to an outer bevel of the sealing material wall. The cover board covers above the image sensing chip, and is adhered to the top surface of the limiting dam and the sealing material wall through the adhesive layer.

In another aspect, the present disclosure provides a method for manufacturing an image sensing device. The method for manufacturing the image sensing device includes at least the following steps: fixing an image sensing chip on an upper surface of a carrier substrate; providing a plurality of metal wires being respectively connected between a plurality of chip pads of the image sensing chip and a plurality of substrate pads of the carrier substrate; providing a cover board, a limiting dam is formed on a bottom surface of the cover board, the limiting dam including a thermoplastic material being adjacent to the cover board, the cover board having an inner ring portion and an outer ring portion, and a thickness of the inner ring portion being greater than a thickness of the outer ring portion; arranging the limiting dam to surround the sensing area of the image sensing chip, and temporarily fixing the inner ring portion between the sensing area and the plurality of substrate pads; disposing a sealing material wall that extends outward from an outer side surface of the limiting dam to cover the plurality of chip pads and fully cover the plurality of metal wires; removing the cover board and the limiting dam; flattening the sealing material wall so that a flat surface is formed on the sealing material wall; coating an adhesive layer on the flat surface of the sealing material wall; and covering the cover board above the image sensing chip, and adhering the cover board to the top surface of the limiting dam and the sealing material wall through the adhesive layer.

In another aspect, the present disclosure provides an image sensing device. The image sensing device includes a carrier substrate, an image sensing chip, a plurality of metal wires, a sealing material wall, an adhesive layer, and a cover board. An upper surface of the carrier substrate includes a plurality of substrate pads. A rear surface of the image sensing chip is fixed on the upper surface of the carrier substrate. A top surface of the image sensing chip has a sensing area and a plurality of chip pads. The plurality of metal wires are respectively connected between the plurality of substrate pads and the plurality of chip pads. The sealing material wall covers the plurality of chip pads and fully covers the plurality of metal wires. A flat surface is formed on the sealing material wall. The adhesive layer is disposed on the flat surface of the sealing material wall. The cover board is covered above the image sensing chip, and is adhered to the sealing material wall through the adhesive layer.

Therefore, one of the beneficial effects of the method for manufacturing the image sensing device provided by the present disclosure is that, the limiting dam is formed on the cover board beforehand, and the thickness of the limiting dam can be controlled and effectively narrowed, such that the limiting dam is able to support the cover board until the sealing material wall is completed and the cover board is assembled. The manufacturing process of the present disclosure can be less limited by the width between the sensing area of the image sensing chip and the edge of the image sensing chip.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIGS. 1A to 1F are schematic views of the steps of a method for manufacturing an image sensing device according to a first embodiment of the present disclosure;

FIGS. 2A to 2H are schematic views of the steps of the method for manufacturing the image sensing device according to a second embodiment of the present disclosure; and

FIGS. 3A to 3C are schematic views of the steps of the method for manufacturing the image sensing device according to a third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

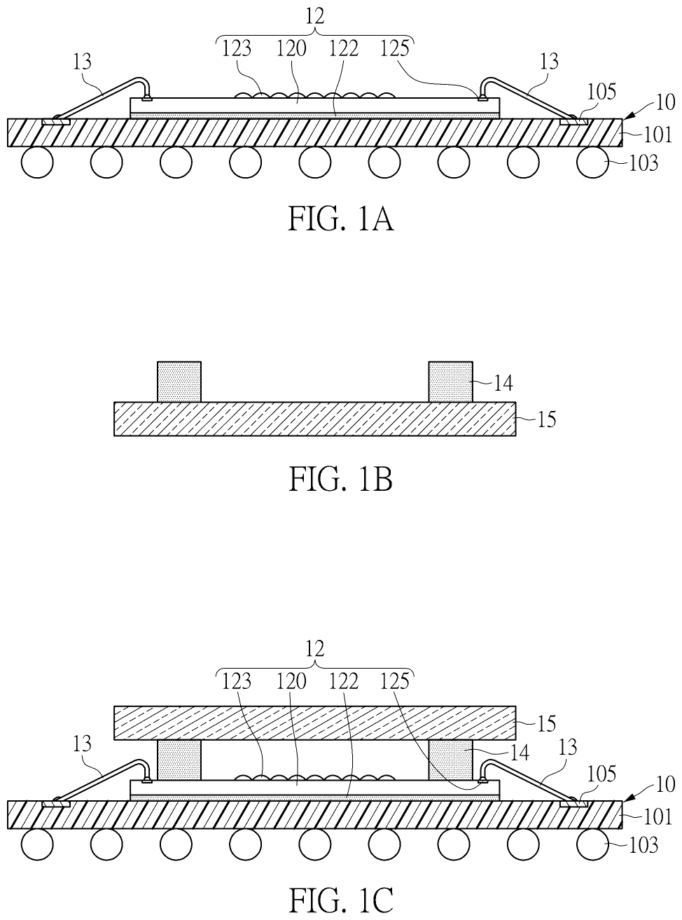

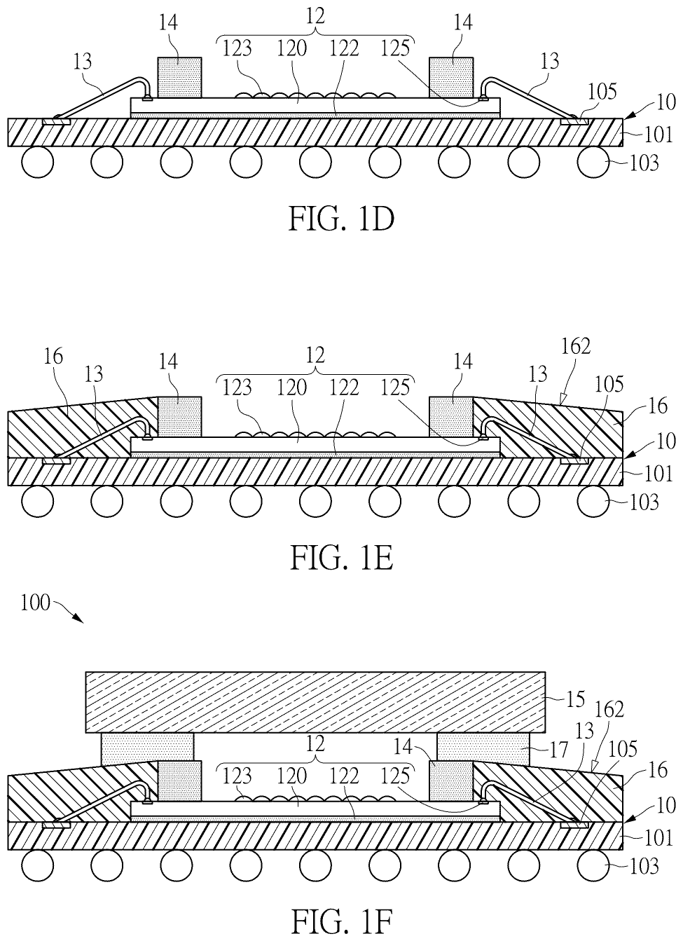

Referring to FIG. 1A to FIG. 1F, a first embodiment of the present disclosure provides a method for manufacturing an image sensing device including at least the following steps:

Referring to FIG. 1A, a first step is a die-adhering step. An image sensing chip 12 is fixed on an upper surface of a carrier substrate 10. A plurality of substrate pads 105 are disposed on an upper surface of a substrate body 101 of the carrier substrate 10. A plurality of external terminals 103 (or called solder balls) are disposed on a lower surface of the substrate body 101. A top surface of a chip body 120 of the image sensing chip 12 has a sensing area 123 and a plurality of chip pads 125. A rear surface (a non-sensing surface) of the image sensing chip 12 is adhered and fixed on the upper surface of the carrier substrate 10 through a cohesive layer 122. The cohesive layer 122 can also absorb some external impact to reduce the external impact applied to the image sensing chip 12.

In a wire-bonding step, a plurality of metal wires 13 are respectively connected between a plurality of chip pads 125 of the image sensing chip 12 and a plurality of substrate pads 105 of the carrier substrate 10.

Referring to FIG. 1B, a wall step is shown. A cover board 15 is provided, and a limiting dam 14 is formed on a bottom surface of the cover board 15. The limiting dam 14 includes a thermoplastic material adjacent to the cover board 15. The limiting dam 14 may be in the shape of a square frame (omitted in the figure) from a top view. In this embodiment, a cross-section of the limiting dam 14 is rectangular-shaped. The limiting dam 14 may be made by pouring molten thermoplastic material into a mold.

Referring to FIG. 1C, the limiting dam 14 is arranged to surround the sensing area 123 of the image sensing chip 12, and fixed between the sensing area 123 and the plurality of substrate pads 105. In this embodiment, a top surface of the limiting dam 14 exceeds the highest position of the plurality of metal wires 13, and the top surface of the limiting dam 14 is flat.

Referring to FIG. 1D, the cover board 15 is removed to separate from the limiting dam 14, in which the limiting dam 14 is still located in the front of the image sensing chip 12.

In this embodiment, the material of the limiting dam 14 is thermoplastic resin. A heating process can be implemented to heat the image sensing device to have a predetermined temperature to reduce an adhesiveness between the limiting dam 14 and the cover board 15, and then the cover board 15 is removed.

A thermal release tape/film is a non-crystalline thermoplastic resin, such as polystyrene, polyvinyl chloride, acrylic resin (having a heat deflection temperature of from 124° C. to 136° C.), styrene-acrylic resin (having a heat deflection temperature of from 88° C. to 104° C.), polycarbonate (PC), and polyethylene terephthalate (PET). In this embodiment, thermoplastic material is used. After reaching a predetermined temperature, the molecular chains begin to loosen and a colloidal layer begins to soften. As a result, the adhesiveness of the tape/film is decreased, the colloidal layer can be easily torn off to achieve the effect of the colloidal layer de-adhesion. In this way, the limiting dam 14 and the cover board 15 can be separated, but the present disclosure is not limited thereto. For example, a functional temporary adhesive can be temporarily adhered between the limiting dam 14 and the cover board 15, and then heating or irradiation by using ultraviolet light can be applied to the functional temporary adhesive to release the adhesiveness.

Referring to FIG. 1E, a sealing material wall 16 extends outward from an outer side surface of the limiting dam 14. The sealing material wall 116 is used to cover the plurality of chip pads 125 and fully cover the plurality of metal wires 13. In this embodiment, the limiting dam 14 limits the position of the sealing material wall 16.

The sealing material wall 16 is located at a periphery of the limiting dam 14, and seals the image sensing chip 12 and the metal wires 13. Specifically, the sealing material wall 16 covers from the upper surface of the carrier substrate 10 to a side surface of the image sensing chip 12. In addition, the sealing material wall 16 covers the plurality of metal wires 13 and a side surface of the limiting dam 14. The sealing material wall 16 and the limiting dam 14 prevent the sensing area 123 from being contaminated by external matter. In addition, the sealing material wall 16 protects the image sensing device from external impact.

The sealing material wall 16 surrounds a whole side surface of the limiting dam 14. An outer bevel 162 of the sealing material wall 16 is slightly inclined relative to the top surface of the limiting dam 14. The sealing material wall 16 may include, for example, epoxy molding compound (EMC). However, the materials of the sealing material wall 16 are not limited to EMC.

Since the limiting dam 14 of this embodiment is formed beforehand on the cover board 15 through a mold, a thickness of the limiting dam 14 is able to be controlled. The narrower the thickness of the limiting dam 14, the better, as long as the limiting dam 14 is able to support the cover board 15 until the sealing material wall 16 is completed.

Referring to FIG. 1F, an adhesive layer 17 is coated on the top surface of the limiting dam 14 and extends to an outer bevel 62 of the sealing material wall 16. A cover board covers above the image sensing chip 12, and the cover board is adhered to the top surface of the limiting dam 14 and the sealing material wall 16 through the adhesive layer 17. The cover board that is finally adhered to the sealing material wall 16 may be the same as the abovementioned cover board 15 that is combined with the limiting dam 14, or the cover board 15 may be another piece. The cover board 15 may be a transparent cover, and a cavity may be formed between the cover board 15 and the image sensing chip 12. The cover board 15 of the present disclosure may be transparent glass or transparent resin.

Referring to FIG. 1F, in summary, through the method for manufacturing an image sensing device of the present disclosure, an image sensing device 100 is completed. The image sensing device 100 includes the carrier substrate 10, the image sensing chip 12, the plurality of metal wires 13, the limiting dam 14, the cover board 15, the sealing material wall 16, and the adhesive layer 17. The upper surface of the carrier substrate 10 includes the plurality of substrate pads 105. A rear surface of the image sensing chip 12 is fixed on the upper surface of the carrier substrate 10. A top surface of the image sensing chip 12 has the sensing area 123 and the plurality of chip pads 125. The plurality of metal wires 13 are respectively connected between the plurality of substrate pads 105 and the plurality of chip pads 125. The limiting dam 14 is disposed on the top surface of the image sensing chip 12. The limiting dam 14 is located between the sensing area 123 and the plurality of substrate pads 105. The sealing material wall 16 extends outward from the outer side surface of the limiting dam 14. The sealing material wall 16 is configured to cover the plurality of chip pads 125 and fully cover the plurality of metal wires 13. The adhesive layer 17 is disposed on the top surface of the limiting dam 14 and extends to an outer bevel of the sealing material wall 16. The cover board 15 covers above the image sensing chip 12, and is adhered to the top surface of the limiting dam 14 and the sealing material wall 16 through the adhesive layer 17. The top surface of the limiting dam 14 exceeds the highest position of the plurality of metal wires 13. The top surface of the limiting dam 14 is flat.

### Second Embodiment

The present disclosure further provides another method for manufacturing the image sensing device that includes at least the steps as follows.

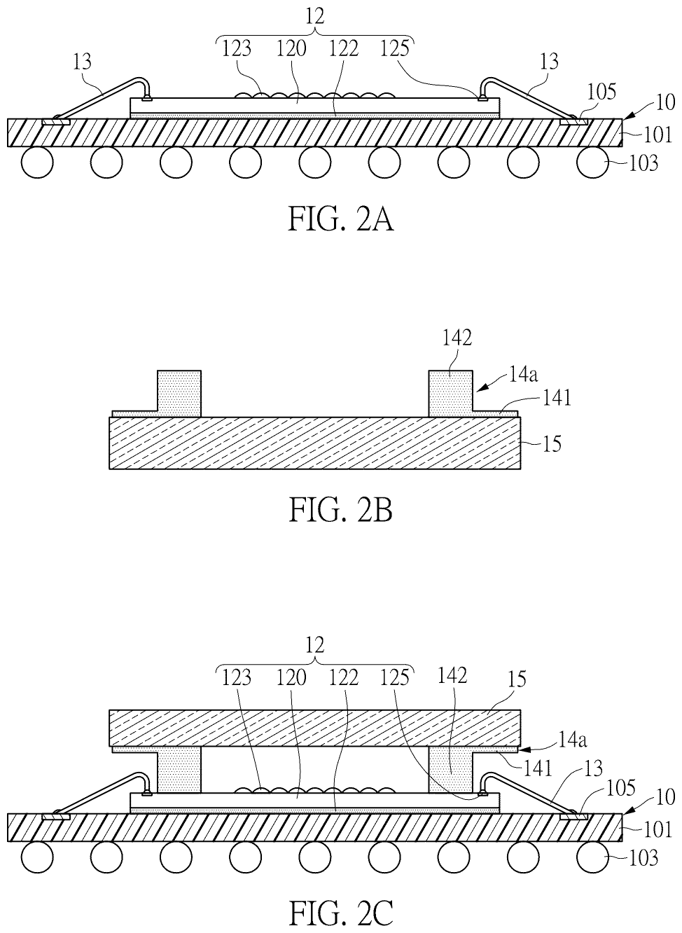

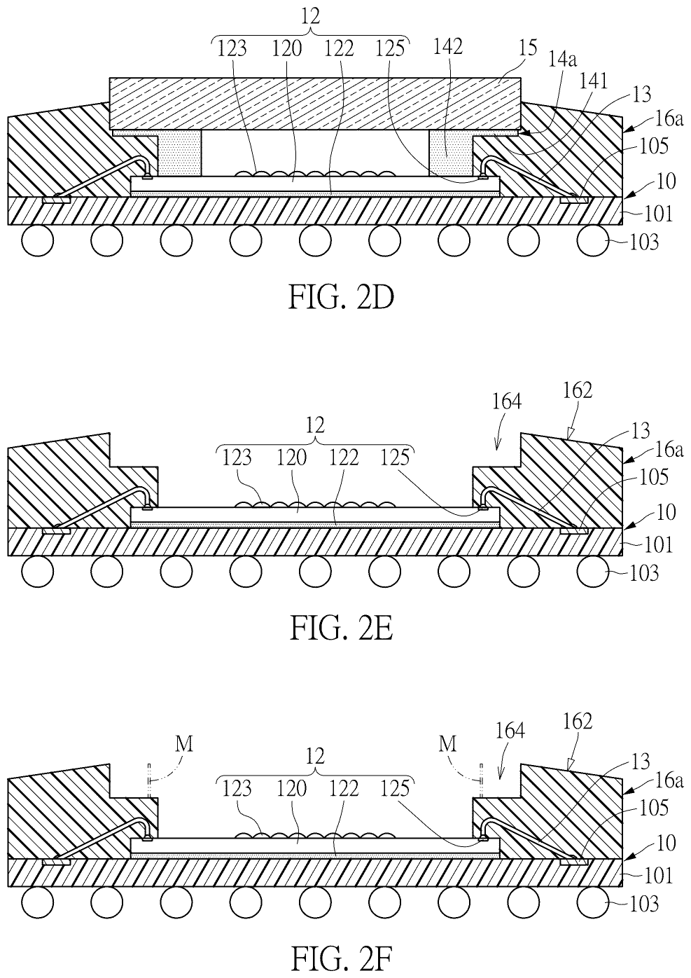

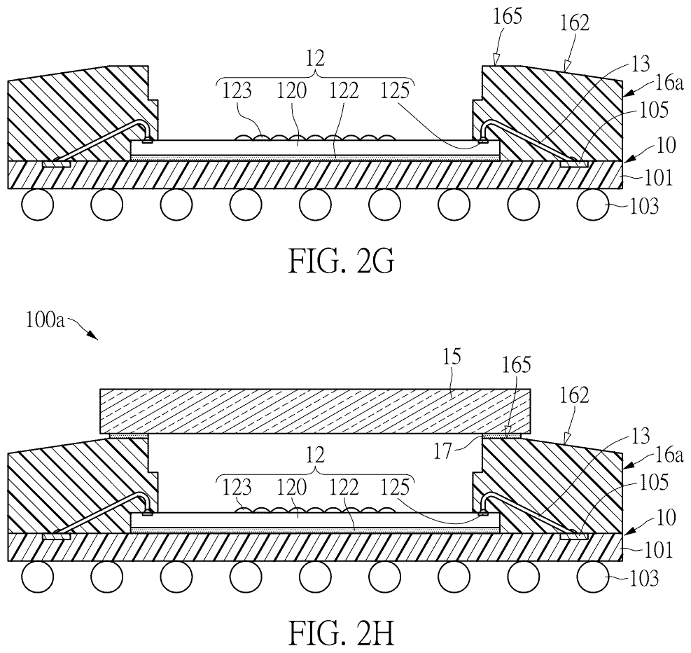

Referring to FIG. 2A, in a die-bonding step, an image sensing chip 12 is fixed on an upper surface of a carrier substrate 10. In a wire-bonding step, a plurality of metal wires 13 are respectively connected between a plurality of chip pads 125 of the image sensing chip 12 and a plurality of substrate pads 105 of the carrier substrate 10.

Referring to FIG. 2B, in a wall-building step, A cover board 15 is provided. A limiting dam 14a is formed on a bottom surface of the cover board 15. The limiting dam 14a is made of thermoplastic material. Different from the previous embodiment, a cross-section of the limiting dam 14a in this embodiment is in a stepped shape. Specifically, the limiting dam 14a has an outer ring portion 141 and an inner ring portion 142. A thickness (or called height) of the inner ring portion 142 is greater than a thickness (or called height) of the outer ring portion 141. In the cross-sectional view, the limiting dam 14a is substantially L-shaped.

Referring to FIG. 2C, the limiting dam 14a is arranged around the sensing area 123 of the image sensing chip 12, and temporarily fixed between the sensing area 123 and the plurality of substrate pads 105. The outer ring portion 141 of the limiting dam 14a is flush with a side end surface of the cover board 15. The outer ring portion 141 of the limiting dam 14a is located above the plurality of chip pads 125 and the plurality of metal wires 13.

Referring to FIG. 2D, a sealing material wall 16a is disposed and extends outward from an outer side surface of the limiting dam 14a. The sealing material wall 16a is configured to cover the plurality of chip pads 125 and fully cover the plurality of metal wires 13. In this embodiment, the sealing material wall 16a further covers a part of the side end surface of the cover board 15, thereby enabling a depression 164 and an outer bevel 162 to be formed. The depression 164 is located above the plurality of chip pads 125. The outer bevel 162 is located at a periphery of the image sensing chip 12, and higher than the limiting dam 14a.

The narrower the thickness of the inner ring portion 142 of the limiting dam 14a, the better, as long as the limiting dam 14 is able to support temporarily the cover board 15 until the sealing material wall 16a is completed.

Referring to FIG. 2E, the cover board 15 is removed, and the limiting dam 14a is removed. As described in the above embodiment, the material of the limiting dam 14a is thermoplastic resin. This embodiment may implement a heating process to heat the image sensing device to have a predetermined temperature to reduce the adhesiveness of the limiting dam 14a, and then remove the cover board 15 and the limiting dam 14a. Different from the previous embodiment, this embodiment further removes the limiting dam 14a.

In this embodiment, the outer ring portion 141 of the limiting dam 14a is located above the plurality of chip pads 125, such that the sealing material wall 16a forms a flat portion above the plurality of chip pads 125. The flat portion in this embodiment is a horizontal surface of the depression 164.

Referring to FIG. 2F and FIG. 2G, this embodiment further includes a step for filling the depression 164. In this flattening step, a higher flat surface 165 adjacent to the outer bevel 162 is formed on the sealing material wall 16a. Specifically, as shown in FIG. 2F, a temporary mold M is disposed as a retaining wall to surround the depression 164. Afterwards, the depression 164 is filled by a material that is the same as the material of the sealing material wall 16a, such that the flat surface 165 that is adjacent to the outer bevel 162 is formed on the sealing material wall 16a.

Referring to FIG. 2H, the adhesive layer 17 is coated on the flat surface 165 of the sealing material wall 16a. Finally, the cover board 15 covers above the image sensing chip 12 and is adhered to the sealing material wall 16a through the adhesive layer 17.

The cover board 15 that is finally adhered to the sealing material wall 16a may be the same as the abovementioned cover board 15 that is combined with the limiting dam 14a, or the cover board 15 may be another piece.

In addition, in another variation of this embodiment, the adhesive layer 17 may be coated on the horizontal surface of the depression 164. The cover board 15 may be adhered directly on the horizontal surface of the depression 164. The cover board 15 that is finally adhered to the sealing material wall 16a may be the same as the abovementioned cover board 15 that is combined with the limiting dam 14a, or the cover board 15 may be another piece, and the width of the cover board 15 in this embodiment can be slightly smaller than the width of the abovementioned cover board 15.

Referring to FIG. 2H, in summary, through the method for manufacturing an image sensing device of the present disclosure, an image sensing device 100a is completed. The image sensing device 100a includes the carrier substrate 10, the image sensing chip 12, the plurality of metal wires 13, the cover board 15, the sealing material wall 16a, and the adhesive layer 17. The upper surface of the carrier substrate 10 includes the plurality of substrate pads 105. A rear surface of the image sensing chip 12 is fixed on the upper surface of the carrier substrate 10. The top surface of the image sensing chip 12 has the sensing area 123 and the plurality of chip pads 125. The plurality of metal wires 13 are respectively connected between the plurality of substrate pads 105 and the plurality of chip pads 125. The sealing material wall 16a covers the plurality of chip pads 125 and fully covers the plurality of metal wires 13. The flat surface 165 is formed on the sealing material wall 16a. The adhesive layer 17 is disposed on the flat surface 165 of the sealing material wall 16a. The cover board 15 covers above the image sensing chip 12 and is adhered to the sealing material wall 16a through the adhesive layer 17.

The sealing material wall 16a further includes the outer bevel 162. The flat surface 165 is adjacent to the outer bevel 162. In this embodiment, the outer bevel 162 is located at the periphery of the image sensing chip 12.

### Third Embodiment

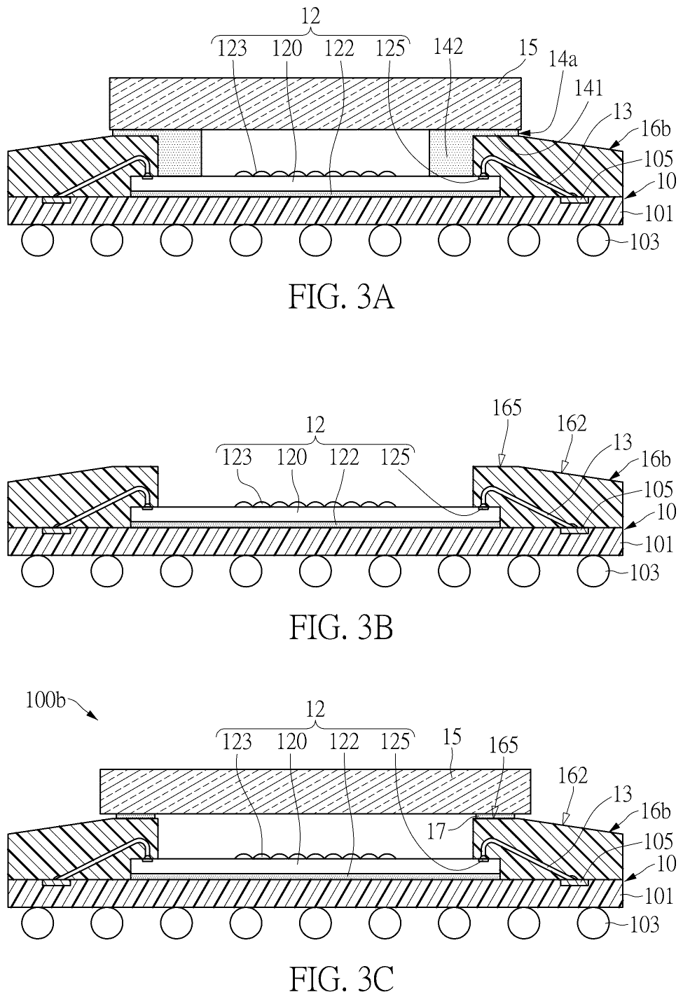

Referring to FIG. 3A to FIG. 3C, a third embodiment of the method for manufacturing the image sensing device is provided. The previous steps of this embodiment are the same as the steps in FIG. 2A to FIG. 2C that can be adapted herein and are not reiterated. As shown in FIG. 3A, this embodiment is different from FIG. 2D of the previous embodiment, in which a sealing material wall 16b extends from the outer side surface of the limiting dam 14a and does not extend to the side end surface of the cover board 15. That is, the sealing material wall 16b is completely located under the cover board 15. Specifically, the sealing material wall 16b is connected to an outer vertical surface of the inner ring portion 142 and a lower horizontal surface of the outer ring portion 141. The sealing material wall 16b may be in contact with an outermost surface of the outer ring portion 141. The sealing material wall 16b covers the periphery of the image sensing chip 12, and fully covers the plurality of metal wires 13. Different from the second embodiment, an overall height of the sealing material wall 16b of this embodiment is lower than an overall height of the sealing material wall 16a of the second embodiment. Similarly, the flat surface 165 and the outer bevel 162 are formed on the sealing material wall 16b. The flat surface 165 is located above the plurality of chip pads 125.

Referring to FIG. 3B, the cover board 15 and the limiting dam 14a are removed. The removing steps are similar to the step in FIG. 2E, and are not reiterated herein.

In this embodiment, the sealing material wall 16b does not have any depression. The sealing material wall 16b has a vertical inner surface that is perpendicular to the upper surface of the image sensing chip 12. The flat surface 165 is connected to the vertical inner surface.

As shown in FIG. 3C, the adhesive layer 17 is coated on the flat surface 165 of the sealing material wall 16b. Finally, in an assembling step, the cover board 15 covers above the image sensing chip 12, and is adhered to the sealing material wall 16b through the adhesive layer 17. The image sensing device 100b is completed.

### Beneficial Effects of the Embodiments

Therefore, one of the beneficial effect of the method for manufacturing the image sensing device provided by the present disclosure is that, the limiting dam is formed on the cover board beforehand, and the thickness of the limiting dam can be controlled and effectively narrowed, such that the limiting dam is able to support the cover board until the sealing material wall is completed and the cover board is assembled. The manufacturing process of the present disclosure can be less limited by the width between the sensing area of the image sensing chip and the edge of the image sensing chip.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method for manufacturing an image sensing device, comprising:
fixing an image sensing chip on an upper surface of a carrier substrate;
providing a plurality of metal wires to respectively connect a plurality of chip pads of the image sensing chip with a plurality of substrate pads of the carrier substrate;
providing a cover board, wherein a limiting dam is formed on a bottom surface of the cover board, wherein the limiting dam includes a thermoplastic material being adjacent to the cover board;
arranging the limiting dam to surround a sensing area of the image sensing chip, and fixing the limiting dam between the sensing area and the plurality of substrate pads;
removing the cover board to separate the cover board from the limiting dam;
disposing a sealing material wall that extends outward from an outer side surface of the limiting dam to cover the plurality of chip pads and fully cover the plurality of metal wires;
coating an adhesive layer on a top surface of the limiting dam and extending the adhesive layer to an outer bevel of the sealing material wall; and
covering the cover board above the image sensing chip, and adhering the cover board to the top surface of the limiting dam and the sealing material wall through the adhesive layer.

2. The method according to claim 1, wherein the top surface of the limiting dam exceeds the highest position of the plurality of metal wires, and the top surface of the limiting dam is flat.

3. The method according to claim 1, wherein a cross-section of the limiting dam is rectangular-shaped.

4. The method according to claim 1, wherein the material of the limiting dam is thermoplastic resin.

5. The method according to claim 4, further comprising a heating process that includes: heating the image sensing device to have a predetermined temperature to reduce an adhesiveness between the limiting dam and the cover board, and removing the cover board.

6. An image sensing device comprising:
a carrier substrate, wherein an upper surface of the carrier substrate includes a plurality of substrate pads;
an image sensing chip, wherein a rear surface of the image sensing chip is fixed on the upper surface of the carrier substrate, and a top surface of the image sensing chip has a sensing area and a plurality of chip pads;
a plurality of metal wires respectively connected between the plurality of substrate pads and the plurality of chip pads;
a limiting dam disposed on the top surface of the image sensing chip and located between the sensing area and the plurality of substrate pads;
a sealing material wall extending outward from an outer side surface of the limiting dam, wherein the sealing material wall is configured to cover the plurality of chip pads and fully cover the plurality of metal wires;
an adhesive layer disposed on a top surface of the limiting dam and extending to an outer bevel of the sealing material wall; and
a cover board covering above the image sensing chip and adhered to the top surface of the limiting dam and the sealing material wall through the adhesive layer.

7. The image sensing device according to claim 6, wherein the top surface of the limiting dam exceeds the highest position of the plurality of metal wires, and the top surface of the limiting dam is flat.

8. The image sensing device according to claim 6, wherein a cross-section of the limiting dam is rectangular-shaped.

9. A method for manufacturing an image sensing device comprising:
fixing an image sensing chip on an upper surface of a carrier substrate;
providing a plurality of metal wires to respectively connect a plurality of chip pads of the image sensing chip with a plurality of substrate pads of the carrier substrate;
providing a cover board, wherein a limiting dam is formed on a bottom surface of the cover board, and the limiting dam includes a thermoplastic material being adjacent to the cover board; wherein the cover board has an inner ring portion and an outer ring portion, and a thickness of the inner ring portion is greater than a thickness of the outer ring portion;
arranging the limiting dam to surround the sensing area of the image sensing chip, and temporarily fixing the inner ring portion between the sensing area and the plurality of substrate pads;
disposing a sealing material wall extending outward from an outer side surface of the limiting dam, wherein the sealing material wall is configured to cover the plurality of chip pads and fully cover the plurality of metal wires;
removing the cover board and the limiting dam;
flattening the sealing material wall so that a flat surface is formed on the sealing material wall;
coating an adhesive layer on the flat surface of the sealing material wall; and
covering the cover board above the image sensing chip, and adhering the cover board to the top surface of the limiting dam and the sealing material wall through the adhesive layer.

10. The method according to claim 9, wherein the outer ring portion of the limiting dam is located above the plurality of chip pads and the plurality of metal wires so that the flat surface is located above the plurality of chip pads.

11. The method according to claim 10, wherein the outer ring portion of the limiting dam is flush with a side end surface of the cover board.

12. The method according to claim 9, wherein the material of the limiting dam is thermoplastic resin.

13. The method according to claim 12, further comprising a heating process that includes: heating the image sensing device to have a predetermined temperature to reduce an adhesiveness between the limiting dam and the cover board, and removing the cover board.

14. The method according to claim 9, wherein the sealing material wall extends outward from the outer side surface of the limiting dam, a part of the sealing material wall extends to a side end surface of the cover board, and the sealing material wall is configured to cover an edge of the image sensing chip and fully cover the plurality of metal wires; wherein the process of removing the cover board and the limiting dam enables a depression and an outer bevel to be formed on the sealing material wall, the depression is located above the plurality of chip pads, and the outer bevel is located above a periphery of the image sensing chip.

15. The method according to claim 14, wherein the flat surface is located on a flat portion of the depression, and the cover board covers on the depression.

16. The method according to claim 14, further comprising: filling the depression so that the flat surface is adjacent to the outer bevel.

17. A image sensing device, comprising:
a carrier substrate, wherein an upper surface of the carrier substrate includes a plurality of substrate pads;
an image sensing chip, wherein a rear surface of the image sensing chip is fixed on the upper surface of the carrier substrate, and a top surface of the image sensing chip has a sensing area and a plurality of chip pads;
a plurality of metal wires respectively connected between the plurality of substrate pads and the plurality of chip pads;
a sealing material wall covering the plurality of chip pads and fully covering the plurality of metal wires, wherein a flat surface is formed on the sealing material wall;
an adhesive layer disposed on the flat surface of the sealing material wall; and
a cover board covering above the image sensing chip and adhered to the sealing material wall through the adhesive layer.

18. The image sensing device according to claim 17, wherein the sealing material wall further has an outer bevel, the flat surface is adjacent to the outer bevel, and the outer bevel is located at a periphery of the image sensing chip.

19. The image sensing device according to claim 17, wherein the flat surface is located above the plurality of chip pads.
